(19) United States
(12) Patent Application Publication
(10) Pub. No.: US 2024/0372614 A1
(43) Pub. Date: Nov. 7, 2024

(54) OPTICAL SPACE COMMUNICATION DEVICE AND OPTICAL SPACE COMMUNICATION METHOD

(71) Applicant: NIPPON TELEGRAPH AND TELEPHONE CORPORATION, Tokyo (JP)

(72) Inventors: Takeshi IMAI, Musashino-shi, Tokyo (JP); Naotaka SHIBATA, Musashino-shi, Tokyo (JP); Shin KANEKO, Musashino-shi, Tokyo (JP); Rintaro HARADA, Musashino-shi, Tokyo (JP)

(73) Assignee: NIPPON TELEGRAPH AND TELEPHONE CORPORATION, Tokyo (JP)

(21) Appl. No.: 18/284,535

(22) PCT Filed: Apr. 2, 2021
(86) PCT No.: PCT/JP2021/014372

§ 371 Date: Sep. 28, 2023

(51) Int. Cl. H04B 10/11; H01S 5/00; H01S 5/02251

(52) U.S. Cl. CPC H04B 10/11; H01S 5/0021; H01S 5/02251

(57) ABSTRACT

According to an embodiment, an optical space communication device includes: an optical antenna configured to receive laser light emitted by multiplexing a main signal to be communicated and a control signal used to maintain or control communication; an optical branching element configured to branch the laser light received by the optical antenna into a plurality of pieces of laser light; a first optical fiber configured to transmit one of the pieces of laser light branched by the optical branching element to a light reception element; a second optical fiber configured to have a larger core diameter than a core diameter of the first optical fiber and transmit another piece of laser light branched by the optical branching element to the light reception element; and an extraction unit configured to extract the control signal from the other piece of laser light transmitted by the second optical fiber.

### TECHNICAL FIELD

The present invention relates to an optical space communication device and an optical space communication method.

### BACKGROUND ART

In 5th generation mobile communication systems (5G) or the like, in addition to wireless communication by radio waves and wired communication by optical fibers, optical wireless communication technologies for transmitting a signal using spatial light have been examined.

For example, in space communication, transmission devices modulate and multiplex control signals related to communication maintenance such as instructions and device information notifications and signals (main signals) which are the main purpose of communication by different modulation schemes (for example, see Non Patent Literature 1). Further, in optical space communication in which light is used, transmission devices drive laser light sources (LD: laser diodes) and emit signals obtained by modulating and multiplexing main signals and control signals from optical antennas as a laser beam (laser light).

Then, reception devices for optical space communication receive laser light with optical antennas and cause laser light to be incident on light reception elements (photodiodes (PDs)) via optical elements such as reflection mirrors, condensing lenses, and single-mode optical fibers arranged at subsequent stages (for example, see Non Patent Literature 2). Then, the reception devices separate and extract the main signals and the control signals from outputs of the PDs and demodulate the main signals and the control signals.

### CITATION LIST

### Non Patent Literature

Non Patent Literature 1: Kazuki Takeda and five others, “NR Physical Layer Specification in 5G”, NTT DOCOMO Technical Journal, Vol. 26 No. 3, November 2018, pp. 47-58
Non Patent Literature 2: Yoshinori Arimoto, “Design and Performance Evaluation of Spatial Optical Communication Devices by Single-mode Fiber Coupling,” Journal of The Institute of Electronics, Information and Communication Engineers (IEICE) C Vol. J91-C No. 1, January 2008, pp. 38-49

### SUMMARY OF INVENTION

### Technical Problem

For example, in optical space communication in which laser light is used, reception devices are arranged to face the optical axis of the laser light transmitted by transmission devices, and light is received by introducing the laser light into the cores of single-mode optical fibers.

However, a positional relationship between the optical axis and a reception device may change from moment to moment due to disturbances such as vibration of a device or atmospheric disturbance. In this case, there is a problem that introduction of laser light into a single-mode optical fiber fails due to a minute deviation in the optical axis, and both the main signal and the control signal may be lost.

If the main signal is lost, the lost signal can be compensated for by performing retransmission. On the other hand, if the control signal is lost, there is a possibility of maintenance of communication failing. Accordingly, the control signal is required to avoid a loss more than the main signal.

The present invention has been made in view of the above-described problems, and an objective of the present invention is to provide an optical space communication device and an optical space communication method capable of reducing a loss of a control signal even when a main signal is lost due to positional deviation of an optical axis.

### Solution to Problem

According to an embodiment of the present invention, an optical space communication device includes: an optical antenna configured to receive laser light emitted by multiplexing a main signal to be communicated and a control signal used to maintain or control communication; an optical branching element configured to branch the laser light received by the optical antenna into a plurality of pieces of laser light; a first optical fiber configured to transmit one of the pieces of laser light branched by the optical branching element to a light reception element; a second optical fiber configured to have a larger core diameter than a core diameter of the first optical fiber and transmit another piece of laser light branched by the optical branching element to the light reception element; and an extraction unit configured to extract the control signal from the other piece of laser light transmitted by the second optical fiber.

According to an embodiment of the present invention, an optical space communication method includes: a reception step of receiving laser light emitted by multiplexing a main signal to be communicated and a control signal used to maintain or control communication; an optical branching step of branching the received laser light into a plurality of pieces of laser light; a first transmission step of causing a first optical fiber to transmit one of the pieces of branched laser light to a light reception element; a second transmission step of causing a second optical fiber that has a larger core diameter than a core diameter of the first optical fiber to transmit another piece of branched laser light to the light reception element; and an extraction step of extracting the control signal from the other piece of laser light transmitted by the second optical fiber.

### Advantageous Effects of Invention

According to the present invention, it is possible to reduce a loss of a control signal even when a main signal is lost due to positional deviation of an optical axis.

### BRIEF DESCRIPTION OF DRAWINGS

FIG. 1 is a diagram illustrating a first configuration example of an optical space communication device according to an embodiment.

FIG. 2 is a diagram illustrating a second configuration example of the optical space communication device according to the embodiment.

FIG. 3 is a diagram illustrating a third configuration example of the optical space communication device according to the embodiment.

FIG. 4 is a diagram illustrating a fourth configuration example of the optical space communication device according to the embodiment.

FIG. 5 is a diagram illustrating an overview of an optical space communication system that performs optical space communication in which laser light is used.

FIG. 6 is a diagram illustrating a configuration of an optical space communication device according to a comparative example.

### DESCRIPTION OF EMBODIMENTS

Before an optical space communication device according to an embodiment is described, the background of the present invention will be specifically described first.

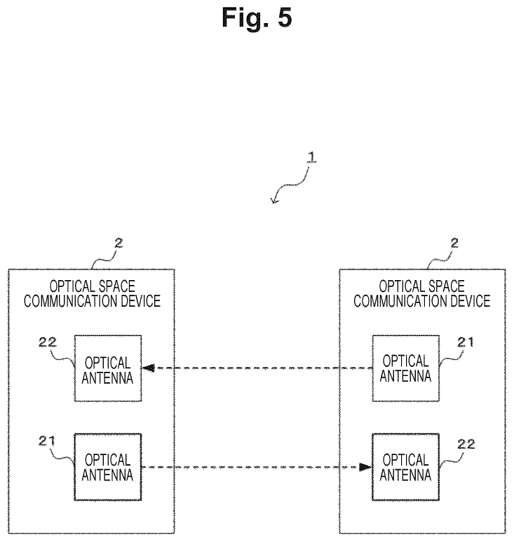

FIG. 5 is a diagram illustrating an overview of an optical space communication system 1 that performs optical space communication in which laser light is used. As illustrated in FIG. 5, in the optical space communication system 1, for example, two optical space communication devices 2 perform bidirectional space communication in which spatial light such as laser light is used.

Each of the optical space communication devices 2 includes an optical antenna 21 for transmission and an optical antenna 22 for reception and has a function as an optical space transmission device and a function as an optical space reception device. The optical space communication device 2 may be configured to have only either a function as an optical space transmission device or a function as an optical space reception device.

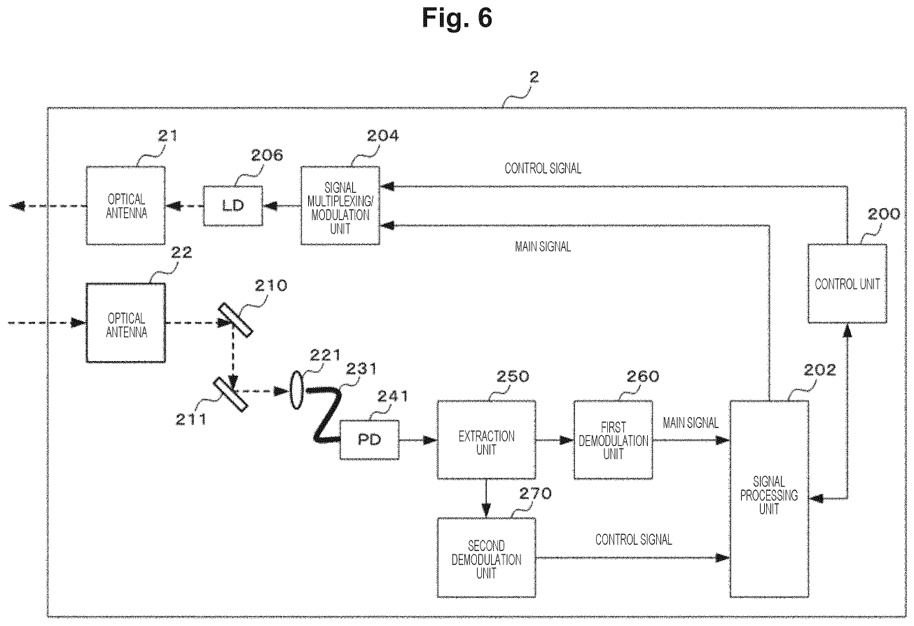

FIG. 6 is a diagram illustrating a configuration of an optical space communication device 2 according to a comparative example. As illustrated in FIG. 6, the optical space communication device 2 according to the comparative example includes a control unit 200, a signal processing unit 202, a signal multiplexing/modulation unit 204, a laser light source (LD: laser diode) 206, an optical antenna 21, an optical antenna 22, a reflection mirror 210, a reflection mirror 211, a condensing lens 221, a single-mode optical fiber (first optical fiber) 231, a light reception element (PD: photodiode) 241, an extraction unit 250, a first demodulation unit 260, and a second demodulation unit 270.

The control unit 200 controls each unit included in the optical space communication device 2. For example, the control unit 200 generates a control signal including an instruction, a device information notification, and the like used to maintain or control communication when the optical space communication device 2 performs optical space communication in which laser light is used with another optical space communication device 2, and outputs the control signal to the signal multiplexing/modulation unit 204.

The signal processing unit 202 performs predetermined signal processing under the control of the control unit 200. For example, the signal processing unit 202 generates a main signal which is a target (main purpose) of optical space communication in which laser light is used, and outputs the main signal to the signal multiplexing/modulation unit 204.

The signal multiplexing/modulation unit 204 modulates and multiplexes the control signal output from the control unit 200 and the main signal output from the signal processing unit 202 in conformity with different modulation schemes, respectively, and outputs a multiplexed signal to the laser light source 206.

The laser light source 206 is driven with the signal output from the signal multiplexing/modulation unit 204 to generate modulated laser light and output the laser light to the optical antenna 21.

The optical antenna 21 forms an image of the laser light output from the laser light source 206 with, for example, diffraction limit accuracy, shapes the laser light to be appropriate for optical space communication, and emits the laser light to a space toward the optical antenna 22 included in the other optical space communication device 2.

The optical antenna 22 receives the laser light emitted from the optical antenna 21 included in the other optical space communication device 2 and outputs the laser light toward the reflection mirror 210.

The reflection mirror 210 reflects the laser light output from the optical antenna 22 toward the reflection mirror 211. The reflection mirror 211 reflects the laser light reflected from the reflection mirror 210 toward the condensing lens 221.

The condensing lens 221 condenses the laser light reflected by the reflection mirror 211 and forms an image toward the core of the single-mode optical fiber 231.

The single-mode optical fiber 231 is, for example, an optical fiber that has an effective opening diameter (mode field diameter) of about 10 μm. The single-mode optical fiber 231 transmits the laser light of which the image is formed by the condensing lens 221 to the light reception element 241.

The light reception element 241 is an optical signal reception element that receives the laser light transmitted by the single-mode optical fiber 231, performs photoelectric conversion, and outputs a signal to the extraction unit 250.

The extraction unit 250 separates and extracts the control signal and the main signal modulated from the signal photoelectrically converted by the light reception element 241, outputs the modulated main signal to the first demodulation unit 260, and outputs the modulated control signal to the second demodulation unit 270.

The first demodulation unit 260 is a main signal demodulation unit that demodulates the main signal extracted by the extraction unit 250 and outputs the demodulated main signal to the signal processing unit 202. The second demodulation unit 270 is a control signal demodulation unit that demodulates the control signal extracted by the extraction unit 250 and outputs the demodulated control signal to the signal processing unit 202.

The optical space communication device 2 may be configured such that the signal multiplexing/modulation unit 204 further performs error correction coding and each of the first demodulation unit 260 and the second demodulation unit 270 performs decoding. The optical space communication device 2 has a configuration in which one light reception element 241 is connected to one single-mode optical fiber 231, but may have a configuration including a hybrid light reception element in which a plurality of light reception elements 241 is connected to one single-mode optical fiber 231.

In the optical space communication device 2, higher-speed and larger-capacity communication is required for the main signal compared with the control signal. For example, the main signal is required to be transmitted by increasing the number of levels of multi-modulation or increasing a bit rate. Therefore, to receive the main signal, required reception optical power tends to increase. Conversely, the control signal is sufficient through low-speed and small-capacity communication, and the required reception optical power can remain low.

In the optical space communication device 2, a positional relationship between an optical axis of the received laser light and an opening of the single-mode optical fiber 231 may change due to disturbance such as vibration or atmospheric disturbance of the device.

Accordingly, the optical space communication device according to the embodiment is configured to be able to reduce a loss of the control signal even when the main signal is lost due to a positional deviation of the optical axis.

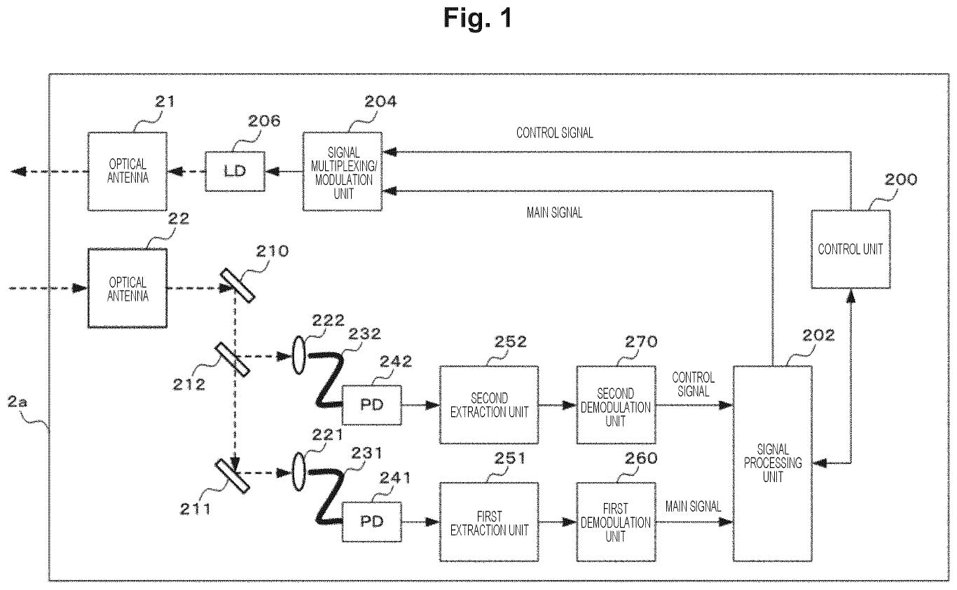

Next, a plurality of configuration examples of the optical space communication device according to the embodiment will be described with reference to FIGS. 1 to 4. In optical space communication devices 2a, 2b, 2c, and 2d according to the embodiments illustrated in FIGS. 1 to 4, substantially the same configurations as those of the optical space communication device 2 illustrated in FIG. 6 are denoted by the same reference numerals.

FIG. 1 is a diagram illustrating a configuration example of the optical space communication device 2a according to an embodiment. As illustrated in FIG. 1, the optical space communication device 2a includes a control unit 200, a signal processing unit 202, a signal multiplexing/modulation unit 204, a laser light source 206, an optical antenna 21, an optical antenna 22, a reflection mirror 210, a reflection mirror 211, a beam splitter 212, a condensing lens 221, a condensing lens 222, a single-mode optical fiber 231, a large-core-diameter optical fiber 232, a light reception element 241, a light reception element 242, a first extraction unit 251, a second extraction unit 252, a first demodulation unit 260, and a second demodulation unit 270.

The beam splitter 212 is an optical branching element that branches the laser light received by the optical antenna 22 into a plurality of pieces of laser light. Specifically, the beam splitter 212 reflects a part of the laser light received by the optical antenna 22 toward the condensing lens 222, and transmits the remaining laser light toward the reflection mirror 211.

The condensing lens 221 condenses the laser light transmitted by the beam splitter 212 and reflected by the reflection mirror 211 and forms an image toward the core of the single-mode optical fiber 231.

Here, the single-mode optical fiber 231 is a first optical fiber that transmits one of the pieces of the laser light branched by the beam splitter 212 to the light reception element 241.

The light reception element 241 receives the laser light transmitted by the single-mode optical fiber 231, performs photoelectric conversion, and outputs a signal to the first extraction unit 251.

The first extraction unit 251 extracts the main signal modulated from the signal photoelectrically converted by the light reception element 241 and outputs the main signal to the first demodulation unit 260.

The condensing lens 222 condenses the laser light reflected by the beam splitter 212 and forms an image toward the core of the large-core-diameter optical fiber 232.

The large-core-diameter optical fiber 232 transmits the laser light branched through reflection by the beam splitter 212 to the light reception element 242 that has a larger core diameter larger than the single-mode optical fiber 231. Here, the large-core-diameter optical fiber 232 is a second optical fiber that transmits the laser light of which the image is formed by the condensing lens 222 to the light reception element 242. The large-core-diameter optical fiber 232 may be a multimode optical fiber or the like.

The light reception element 242 is an optical signal reception element that receives the laser light transmitted by the large-core-diameter optical fiber 232, performs photoelectric conversion, and outputs a signal to the second extraction unit 252.

The second extraction unit 252 extracts a modulated control signal from the laser light transmitted by the large-core-diameter optical fiber 232 and outputs the control signal to the second demodulation unit 270.

That is, the optical space communication device 2a causes a part of the laser light in which the control signal and the main signal are multiplexed using the beam splitter 212 that performs optical splitting to be incident on the large-core-diameter optical fiber 232 that has a larger core diameter than the single-mode optical fiber 231. Then, the optical space communication device 2a extracts the control signal from the signal that has passed through the large-core-diameter optical fiber 232.

The optical space communication device 2a causes the laser light transmitted by the beam splitter 212 to be incident on the single-mode optical fiber 231 and extracts the main signal from the signal passing through the single-mode optical fiber 231.

An optical fiber having a large core diameter is generally unsuitable for high-speed signal transmission. However, since a speed of the control signal is low, even an optical fiber that has a large core diameter can be transmitted.

In addition, the large-core-diameter optical fiber 232 has a larger core diameter than the single-mode optical fiber 231. Therefore, even when the optical axis of the laser light deviates, introduction of the laser light is easier than in the single-mode optical fiber 231.

Even if the introduction of the laser light into the large-core-diameter optical fiber 232 fails due to the deviation in the optical axis and an optical loss occurs, the optical space communication device 2a is highly likely to be able to receive the control signal because required reception optical power of the control signal is less than required reception optical power of the main signal.

Since the required reception optical power of the control signal is less than the required reception optical power of the main signal, a splitting ratio of the light by the beam splitter 212 may be set to be small for the light reception element 242 and great for the light reception element 241.

The optical space communication device 2a may be configured such that a part of the laser light is split by a second beam splitter (not illustrated) and is input to an optical element that measures an optical axis position of the laser light. In this case, the second beam splitter may be disposed immediately before the condensing lens 222 or immediately before the condensing lens 221.

In this way, the optical space communication device 2a can reduce a likelihood of the control signal being lost even if introduction of the laser light into the single-mode optical fiber 231 fails due to the positional deviation of the optical axis and the main signal cannot be received.

Note that the main signal and the control signal may be time-multiplexed so as to be alternately transmitted at predetermined time intervals, or the control signal may be intensity-modulated with respect to the main signal. When the main signal and the control signal are time-multiplexed, the first extraction unit 251 and the second extraction unit 252 extract the main signal or the control signal at predetermined time intervals. When the main signal and the control signal are intensity-modulated, each of the first extraction unit 251 and the second extraction unit 252 extracts the main signal or the control signal using a predetermined frequency filter.

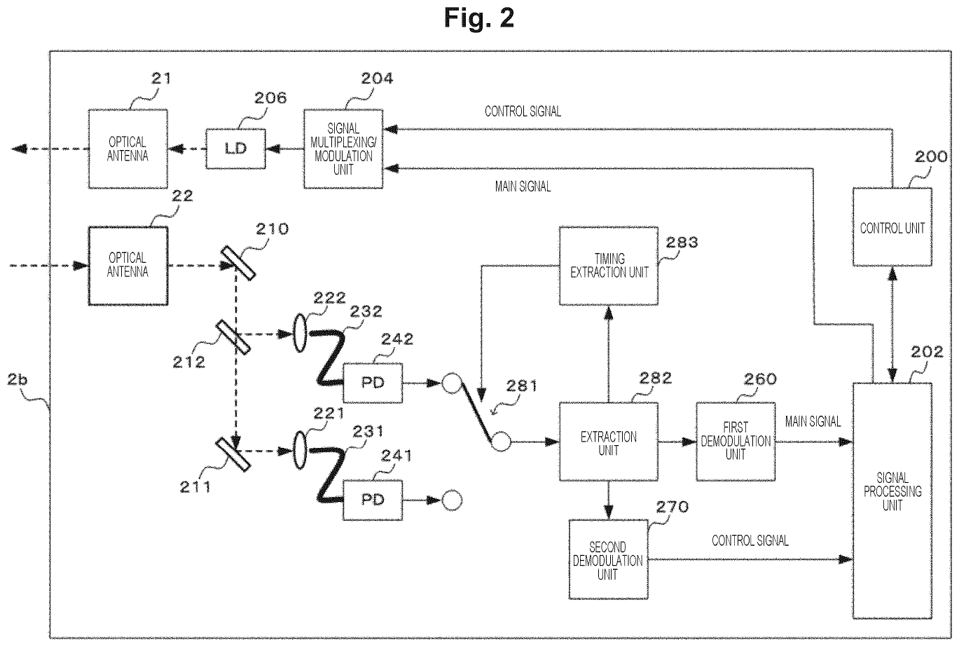

FIG. 2 is a diagram illustrating a configuration example of the optical space communication device 2b according to an embodiment. As illustrated in FIG. 2, the optical space communication device 2b includes the control unit 200, a signal processing unit 202, the signal multiplexing/modulation unit 204, the laser light source 206, the optical antenna 21, the optical antenna 22, the reflection mirror 210, the reflection mirror 211, the beam splitter 212, the condensing lens 221, the condensing lens 222, the single-mode optical fiber 231, the large-core-diameter optical fiber 232, the light reception element 241, the light reception element 242, a switch 281, an extraction unit 282, a timing extraction unit 283, the first demodulation unit 260, and the second demodulation unit 270.

The switch 281 is a 2-to-1 changeover switch that selects one of a signal output from the light reception element 241 and a signal output from the light reception element 242 based on information indicating a timing extracted by the timing extraction unit 283 and switches a signal path such that the selected signal is output to the extraction unit 282.

For example, the switch 281 performs switching such that one of the signal output from the light reception element 241 receiving one piece of laser light transmitted by the single-mode optical fiber 231 and the signal output from the light reception element 242 receiving another piece of laser light transmitted by the large-core-diameter optical fiber 232 is input to the extraction unit 282 based on a timing extracted by the timing extraction unit 283 when the optical antenna 22 receives the laser light in which the main signal and the control signal are time-multiplexed.

The extraction unit 282 separates and extracts the control signal and the main signal from the signal input via the switch 281, outputs the modulated main signal to the first demodulation unit 260, and outputs the modulated control signal to the second demodulation unit 270. The extraction unit 282 outputs a signal input via the switch 281 to the timing extraction unit 283.

The timing extraction unit 283 extracts a timing at which at least one of the main signal and the control signal is transmitted to one of light reception element 241 and light reception element 242 based on the signal input from extraction unit 282, and outputs information indicating the extracted timing to the switch 281.

That is, the timing extraction unit 283 extracts the timing based on at least one of the plurality of pieces of laser light branched by beam splitter 212. For example, the timing extraction unit 283 may extract a timing at which the main signal is transmitted to the light reception element 241 or may extract a timing at which the control signal is transmitted to the light reception element 242.

As a result, the extraction unit 282 may extract the main signal from the laser light transmitted by the single-mode optical fiber 231 or may extract the control signal from the laser light transmitted by the large-core-diameter optical fiber 232 based on the timing extracted by the timing extraction unit 283.

The optical space communication device 2b is configured such that, for example, when an operation starts, the switch 281 outputs an output from one of the light reception element 241 and the light reception element 242 to the extraction unit 282.

Thereafter, in the optical space communication device 2b, for example, when a signal is input from one of the light reception element 241 and the light reception element 242 to the extraction unit 282, the timing extraction unit 283 measures each input timing from the control signal and the main signal alternately transmitted at predetermined time intervals. Then, the timing extraction unit 283 performs driving so that the switch 281 is switched in synchronization with the input timing of each of the measured control signal and main signal.

For example, the switch 281 outputs the signal output from the light reception element 242 to the extraction unit 282 at the timing at which the control signal is transmitted, and outputs the signal output from the light reception element 241 to the extraction unit 282 at the timing at which the main signal is transmitted.

As described above, the optical space communication device 2b can reduce a likelihood of the control signal being lost even if introduction of the laser light into the single-mode optical fiber 231 fails due to the positional deviation of the optical axis and the main signal cannot be received. The optical space communication device 2b can be configured by fewer electronic circuits and the like than the above-described optical space communication devices 2 and 2a.

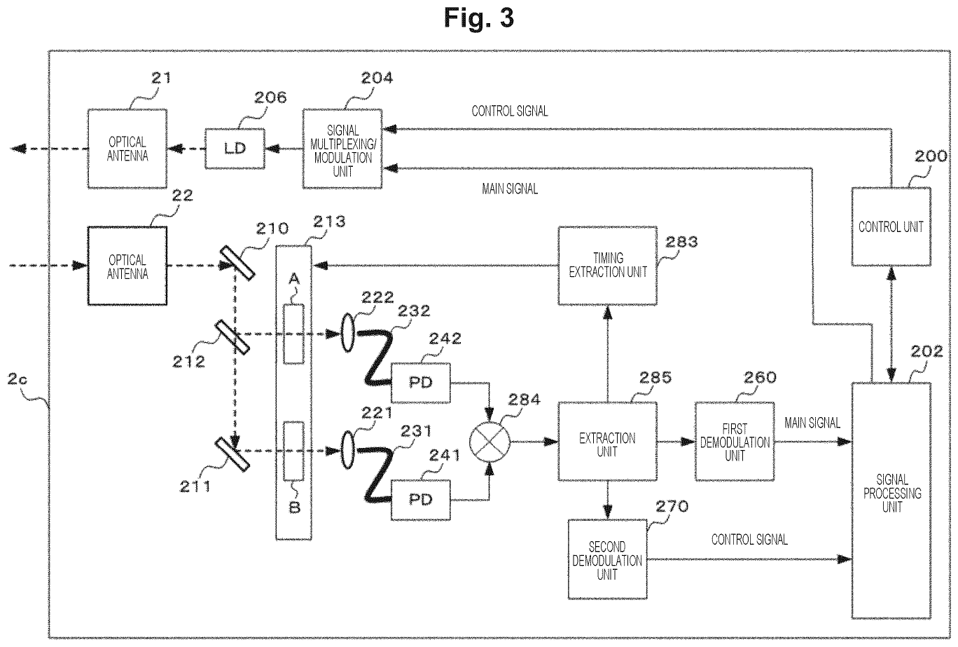

FIG. 3 is a diagram illustrating a configuration example of the optical space communication device 2c according to the embodiment. As illustrated in FIG. 3, the optical space communication device 2c includes the control unit 200, the signal processing unit 202, the signal multiplexing/modulation unit 204, the laser light source 206, the optical antenna 21, the optical antenna 22, the reflection mirror 210, the reflection mirror 211 the beam splitter 212, the switching unit 213, the condensing lens 221, the condensing lens 222, the single-mode optical fiber 231, the large-core diameter optical fiber 232, the light reception element 241, the light reception element 242, the timing extraction unit 283, a combination unit 284, an extraction unit 285, the first demodulation unit 260, and the second demodulation unit 270.

The switching unit 213 includes optical shutters A and B. For example, when the optical antenna 22 receives laser light in which a main signal and a control signal are time-multiplexed, one of the optical shutters A and B is caused to transmit the laser light and the other optical shutter is caused to block the laser light.

For example, the switching unit 213 performs switching such that the light reception element 241 receives one of the pieces of laser light branched by the beam splitter 212 and the light reception element 242 receives another piece of laser light branched by the beam splitter 212 based on a timing extracted by the timing extraction unit 283.

The optical shutters A and B are not limited to the above-described arrangement. For example, the optical shutters A and B may be arranged in the middle of each of the single-mode optical fiber 231 and the large-core diameter optical fiber 232, or may be arranged at a rear stage of each of the single-mode optical fiber 231 and the large-core diameter optical fiber 232.

The combination unit 284 combines a signal output from the light reception element 241 receiving one of the pieces of laser light branched by the beam splitter 212 and a signal output from the light reception element 242 receiving another piece of laser light branched by the beam splitter 212, and outputs the combined signal to the extraction unit 285.

The extraction unit 285 separates and extracts the control signal and the main signal from the signal input via the combination unit 284, outputs the modulated main signal to the first demodulation unit 260, and outputs the modulated control signal to the second demodulation unit 270. The extraction unit 285 outputs the signal input via the combination unit 284 to the timing extraction unit 283.

The optical space communication device 2c is configured such that, for example, when an operation starts, the switching unit 213 inputs an output from one of the light reception element 241 and the light reception element 242 to the extraction unit 285.

Thereafter, in the optical space communication device 2c, for example, when the signal is input from one of the light reception element 241 and the light reception element 242 to the extraction unit 285, the timing extraction unit 283 measures each input timing from the control signal and the main signal alternately transmitted at predetermined time intervals. Then, the timing extraction unit 283 performs driving such that the transmission and blocking of the laser light by the optical shutters A and B of the switching unit 213 are switched in synchronization with the input timings of the measured control signal and the main signal.

For example, the switching unit 213 performs switching so that the combination unit 284 outputs the signal output from the light reception element 242 to the extraction unit 285 at a timing at which the control signal is transmitted, and the combination unit 284 outputs the signal output from the light reception element 241 to the extraction unit 285 at a timing at which the main signal is transmitted.

In this way, the optical space communication device 2c can reduce a likelihood of the control signal being lost even if introduction of the laser light into the single-mode optical fiber 231 fails due to the positional deviation of the optical axis and the main signal cannot be received. The optical space communication device 2c can be configured by fewer electronic circuits and the like than the above-described optical space communication devices 2 and 2a.

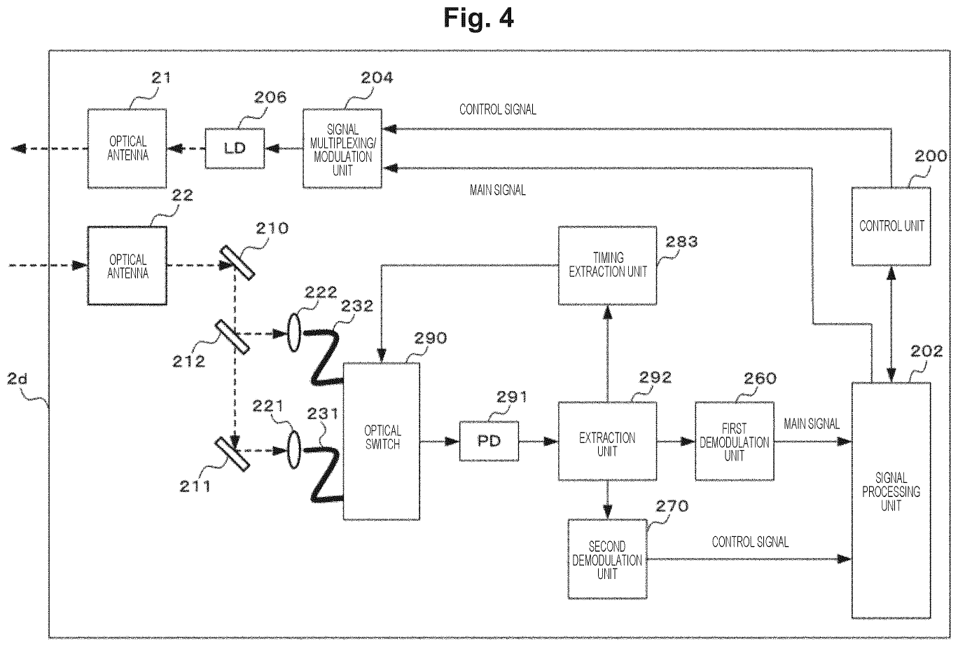

FIG. 4 is a diagram illustrating a configuration example of an optical space communication device 2d according to an embodiment. As illustrated in FIG. 4, the optical space communication device 2d includes the control unit 200, the signal processing unit 202, the signal multiplexing/modulation unit 204, the laser light source 206, the optical antenna 21, the optical antenna 22, the reflection mirror 210, the reflection mirror 211, the beam splitter 212, the condensing lens 221, the condensing lens 222, the single-mode optical fiber 231, the large-core-diameter optical fiber 232, the timing extraction unit 283, an optical switch 290, a light reception element 291, an extraction unit 292, the first demodulation unit 260, and the second demodulation unit 270.

When the optical antenna 22 receives the laser light in which the main signal and the control signal are time-multiplexed, the optical switch 290 performs switching such that one piece of laser light transmitted by the single-mode optical fiber 231 and another piece of laser light transmitted by the large-core-diameter optical fiber 232 are alternately input to the light reception element 291 based on a timing extracted by the timing extraction unit 283.

For example, the optical switch 290 performs switching such that the signal output from the light reception element 242 is output to the light reception element 291 at a timing at which the control signal is transmitted, and the signal output from the light reception element 241 is output to the light reception element 291 at a timing at which the main signal is transmitted.

The light reception element 291 is an optical signal reception element that receives the laser light switched and output by the optical switch 290, performs photoelectric conversion, and outputs a signal to the extraction unit 292.

The extraction unit 292 alternately extracts the control signal and the main signal from the signal output from the light reception element 291 alternately receiving one piece of laser light transmitted by the single-mode optical fiber 231 and another piece of laser light transmitted by the large-core-diameter optical fiber 232. Then, the extraction unit 292 outputs the modulated main signal to the first demodulation unit 260 and outputs the modulated control signal to the second demodulation unit 270. The extraction unit 292 outputs the signal input from the light reception element 291 to the timing extraction unit 283.

The optical space communication device 2d is configured such that, for example, when an operation starts, the optical switch 290 inputs an output from one of the light reception element 241 and the light reception element 242 to the light reception element 291.

Thereafter, in the optical space communication device 2d, when a signal is input from the light reception element 291 to the extraction unit 292, the timing extraction unit 283 measures each of the input timings from the control signal and the main signal alternately transmitted at predetermined time intervals. Then, the timing extraction unit 283 performs driving so that the optical switch 290 switches the output of the laser light in synchronization with the input timings of the measured control signal and main signal.

For example, the optical switch 290 performs switching such that the signal output from the light reception element 242 is output to the light reception element 291 at a timing at which the control signal is transmitted, and the signal output from the light reception element 241 is output to the light reception element 291 at a timing at which the main signal is transmitted.

In this way, the optical space communication device 2d can reduce the likelihood of the control signal being lost even if introduction of the laser light into the single-mode optical fiber 231 fails due to a positional deviation of the optical axis and the main signal cannot be received. The optical space communication device 2d can be configured by fewer electronic circuits and the like than the above-described optical space communication devices 2 and 2a.

### REFERENCE SIGNS LIST

1 Optical space communication system
2, 2a, 2b, 2c, 2d Optical space communication device
21 Optical antenna
22 Optical antenna
200 Control unit
202 Signal processing unit
204 Signal multiplexing/modulation unit
206 Laser light source
210 Reflection mirror
211 Reflection mirror
212 Beam splitter
213 Switching unit
221 Condensing lens
222 Condensing lens
231 Single-mode optical fiber
232 Large-core-diameter optical fiber
241, 242, 291 Light reception element
250 Extraction unit
251 First extraction unit
252 Second extraction unit
260 First demodulation unit
270 Second demodulation unit
281 Switch
282 Extraction unit
283 Timing extraction unit
284 Combination unit
285 Extraction unit
290 Optical switch
292 Extraction unit

1. An optical space communication device including:
an optical antenna configured to receive laser light emitted by multiplexing a main signal to be communicated and a control signal used to maintain or control communication;
an optical branching structure configured to branch the laser light received by the optical antenna into a plurality of pieces of laser light;
a first optical fiber configured to transmit one of the pieces of laser light branched by the optical branching structure to a light receiver;
a second optical fiber configured to have a larger core diameter than a core diameter of the first optical fiber and transmit another piece of laser light branched by the optical branching structure to the light receiver; and
extraction circuitry configured to extract the control signal from the other piece of laser light transmitted by the second optical fiber.

2. The optical space communication device according to claim 1, further comprising:
timing extraction circuitry configured to extract a timing at which at least one of the main signal and the control signal is transmitted to the light receiver based on at least one of the plurality of pieces of laser light branched by the optical branching structure
wherein the extraction circuitry further extracts the main signal from the one piece of laser light transmitted by the first optical fiber based on the timing extracted by the timing extraction circuitry.

3. The optical space communication device according to claim 2, further comprising:
a switch configured to perform switching such that one of a signal output by the light receiver receiving one piece of laser light transmitted by the first optical fiber and a signal output by the light receiver receiving another piece of laser light transmitted by the second optical fiber is input to the extraction circuitry based on the timing extracted by the timing extraction circuitry when the optical antenna receives the laser light in which the main signal and the control signal are time-multiplexed.

4. The optical space communication device according to claim 2, further comprising:
switching circuitry configured to switch between reception of one of the pieces of laser light branched by the optical branching structure by the light receiver and reception of another piece of laser light branched by the optical branching structure element by the light receiver based on the timing extracted by the timing extraction circuitry when the optical antenna receives the laser light in which the main signal and the control signal are time-multiplexed; and
combination circuitry configured to combine a signal output from the light receiver receiving one of the pieces of laser light branched by the optical branching structure and a signal output from the light receiver receiving another piece of laser light branched by the optical branching structure and to output the combined signal to the extraction circuitry.

5. The optical space communication device according to claim 2, further comprising:
an optical switch configured to perform switching such that one piece of laser light transmitted by the first optical fiber and another piece of laser light transmitted by the second optical fiber are alternately input to the light receiver based on the timing extracted by the timing extraction circuitry when the optical antenna receives the laser light in which the main signal and the control signal are time-multiplexed,
wherein the extraction circuitry alternately extracts the control signal and the main signal from the signal output from the light receiver alternately receiving the one piece of laser light transmitted by the first optical fiber and the other piece of laser light transmitted by the second optical fiber.

6. An optical space communication method, comprising:
receiving laser light emitted by multiplexing a main signal to be communicated and a control signal used to maintain or control communication;
branching the received laser light into a plurality of pieces of laser light;
causing a first optical fiber to transmit one of the pieces of branched laser light to a light receiver,
causing a second optical fiber that has a larger core diameter than a core diameter of the first optical fiber to transmit another piece of branched laser light to the light receiver; and
extracting the control signal from the other piece of laser light transmitted by the second optical fiber.

7. The optical space communication method according to claim 6, further comprising:
extracting a timing at which at least one of the main signal and the control signal is transmitted to the light receiver based on at least one of the plurality of pieces of branched laser light.
wherein, in the extracting the control signal, the main signal is further extracted from the one piece of laser light transmitted by the first optical fiber based on the timing extracted in the extracting the timing.
